(19) United States
(12) Patent Application Publication
(10) Pub. No.: US 2026/0282604 A1
(43) Pub. Date: Sep. 17, 2026

(54) THIN QUANTUM BARRIER WITH HIGH ALUMINUM CONTENT FOR ULTRAVIOLET LIGHT EMITTERS

(71) Applicant: The Regents of the University of California, Oakland, CA (US)

(72) Inventors: Yifan Yao, Goleta, CA (US); Matthew S. Wong, Santa Barbara, CA (US); Hongjian Li, Goleta, CA (US); Michael Iza, Goleta, CA (US); Shuji Nakamura, Santa Barbara, CA (US); Steven P. DenBaars, Goleta, CA (US)

(73) Assignee: The Regents of the University of California, Oakland, CA (US)

(21) Appl. No.: 19/162,486

(22) PCT Filed: Mar. 20, 2024
(86) PCT No.: PCT/US24/20692

§ 371 Date: Sep. 5, 2025

Related U.S. Application Data
(60) Provisional application No. 63/491,350, filed on Mar. 21, 2023.

(51) Int. Cl. H10H 20/812; H01S 5/02; H01S 5/30; H01S 5/34; H01S 5/343; H10H 20/01; H10H 20/817; H10H 20/825

(52) U.S. Cl. CPC H10H 20/812; H01S 5/021; H01S 5/0213; H01S 5/0218; H01S 5/3063; H01S 5/309; H01S 5/3407; H01S 5/34333; H01S 5/34346; H10H 20/01335; H10H 20/0137; H10H 20/817; H10H 20/8252; H01S 2301/173; H01S 2302/00

(57) ABSTRACT

A laser diode (LD) or light emitting diode (LED) fabricated on an Aluminum Nitride (AlN) template on a sapphire, bulk AlN, or Silicon Carbide (SiC) substrate, wherein the thickness of the quantum barrier is thinner than a conventional design and the Al content of the quantum barrier is higher than the conventional design. Improved crystal quality and radiative efficiency can be achieved by minimizing the strain from the lattice mismatch during the growth. The result is an efficient UV LD/LED with an emission wavelength between 300 nm and 370 nm.

### CROSS REFERENCE TO RELATED APPLICATION

This application claims the benefit under 35 U.S.C. Section 119 (e) of the following co-pending and commonly-assigned application:
U.S. Provisional Application Ser. No. 63/491,350, filed on Mar. 21, 2023, by Yifan Yao, Matthew S. Wong, Hongjian Li, Michael Iza, Shuji Nakamura and Steven P. DenBaars, entitled “THIN QUANTUM BARRIER WITH HIGH ALUMINUM CONTENT FOR ULTRAVIOLET LIGHT EMITTERS,” attorneys' docket number G&C 30794.0833USP1 (UC 2023-882-1);
which application is incorporated by reference herein.

### STATEMENT REGARDING FEDERALLY SPONSORED RESEARCH AND DEVELOPMENT

This invention was made with Government support under Grant No. W911NF-22-2-0056 awarded by the Army Research Laboratory-Army Research Office. The Government has certain rights in this invention.

### BACKGROUND OF THE INVENTION

### 1. Field of the Invention

The present invention is related to a method of fabricating an ultraviolet light emitting diode (LED) or laser diode (LD) with an emission wavelength below 360 nm with a novel active region design.

### 2. Description of the Related Art

(Note: This application references a number of different publications as indicated throughout the specification by one or more reference numbers in brackets, e.g., [x]. A list of these different publications ordered according to these reference numbers can be found below in the section entitled “References.” Each of these publications is incorporated by reference herein.)

Efficient AlGaN-based LEDs and LDs with emission wavelengths between 300 nm and 360 nm have numerous applications in the fields of lithography, material processing, chemical sensing, data storage, medical treatment, cytometry, etc. This wavelength range is usually referred to as ultraviolet A (UVA) and ultraviolet B (UVB), wherein UVB encompasses a wavelength range of 280-315 nm and UVA encompasses a wavelength range of 315-400 nm. The active region in the device where the light is generated for this wavelength range is usually composed of AlₓGa₁₋ₓN with an Al composition x ranging from 0 to 0.5.

Efficient UV LEDs with a wavelength shorter than 280 nm, commonly referred as ultraviolet C (UVC), wherein UVC encompasses a wavelength range of 100-280 nm, have been demonstrated with external quantum efficiency (EQE) above 10% from multiple reports on AlN templates on sapphire substrates or bulk AlN substrates. Thanks to the rapid developments in high temperature annealing in the last decade, AlN templates with a threading dislocation density (TDD)<5×10⁸ cm⁻² are becoming widely available commercially. With optimized device structure and growth conditions, UVC LEDs grown on these substrates can have high internal quantum efficiency (IQE), reaching above 50%-80%. Due to the low TDD in the substrate, and the small lattice mismatch between the substrate and the active region, the density of non-radiative defects, such as threading dislocations (TDs) that are catastrophic to device operation can be minimized in the active region because of the relatively small amount of strain in the quantum wells (QWs) and barriers (QBs) required for <=280 nm emission. However, adapting the UVC device structure to devices with longer emission wavelength by adjusting the Al composition in the active region is still challenging. Since the Al composition in the active region for UVA emission is much lower, the lattice mismatch and the resulting strain between the low-Al-content active region and AlN template can be expected to be much higher than UVC counterparts. For example, AlGaN with Al composition of 0.2 (typical Al composition in active region for 340 nm emission) can have >2% lattice mismatch from the AlN template. Such a large amount of strain is usually accommodated by forming misfit dislocations (MDs) and hence results in a high density of vertically propagating TDs in the active region (a TDD>5×10⁹ cm⁻²). On the other hand, devices with an even lower Al composition in the active region (an Al composition less than 5%) to target for 360 nm or longer emission can be readily grown on a GaN substrate or GaN template on a sapphire substrate with proper tensile strain management since the lattice mismatch is negligibly small. Therefore, no efficient UV LEDs (EQE >5%) with emission wavelength between 320 and 360 nm has ever been reported to date due to the existence of a high TDD in the active region, commonly referred as a “UVB/UVA gap”.

There have been many attempts to relieve the strain without generating additional defects in the light emitting active region. One of the methods is to introduce superlattice (SL) structures for strain relaxation on the AlN template and grow an active region on the relaxed Si-doped AlGaN thick buffer. More recently, a TDD in the low 10⁹ cm⁻² range was demonstrated on a carefully optimized, highly relaxed, AlGaN SL structure on an AlN substrate and UVA LEDs with EQEs up to 1% were grown on such templates [1], which was still one order of magnitude less efficient than UVC LEDs grown on AlN templates. The other route is to grow UVA devices on thick AlGaN buffers regrown on masked AlN templates with epitaxial lateral overgrowth (ELO). [2] The AlGaN/AlN ELO technique usually requires several microns of regrowth for coalescence, which is expensive and time-consuming, yet the reported TDD is still above low 10⁸ cm⁻². Such problems would only worsen for LD growth with a similar emission wavelength since the laser cladding layers are usually thicker than those of LEDs for better current spreading and the laser active region requires an even lower TDD for minimal loss. Therefore, UV LDs with emission wavelengths between 350-370 nm were never commercialized on GaN templates and there has been no demonstration of reliable LD devices with an emission wavelength between 320-350 nm ever on AlN templates.

As stated previously, the difficulty in fabricating highly efficient UV LEDs/LDs on an AlN template or an AlN substrate with emission wavelength between 300 nm and 360 nm is that the conventional technology cannot prevent the active region from being relaxed by generating new defects, which lowers the radiative efficiency. The radiative efficiency in the UV LED/LD active region can be further reduced by the large polarization field separating the electron and hole wavefunctions, commonly referred to as the quantum confined stark effect (QCSE), by the conventional design.

There is a need for improved device design structures for UV LEDs/LDs on AlN to minimize the deleterious effects present in conventional device structures. The present invention satisfies this need.

### SUMMARY OF THE INVENTION

To overcome the limitations of the prior art described above, the present invention discloses UVA LEDs/LDs grown on AlN templates. The present structure distinguishes itself from the prior art by incorporating thin quantum barriers with a much higher Al composition than quantum wells in the conventional design, which can minimize the generation of new defects and promote the radiative efficiency. This allows for the realization of highly efficient UVA LEDs grown on an AlN template or AlN substrate.

First, a current spreading n-type AlGaN layer can be readily grown on an AlN template on a sapphire or AlN substrate. Because the n-type AlGaN layer should have a higher bandgap than that of the quantum well to minimize the absorption of the light generated from the quantum well, the n-type AlGaN layer should have a higher Al composition than the quantum well, typically above an 0.6 Al composition to minimize the lattice mismatch between itself and the AlN layer, but preferably below an 0.8 Al composition to maximize the conductivity. With only a small amount of strain caused by the lattice mismatch, such an n-type AlGaN layer can be readily grown on the AlN with little to no (<30%) in-plane lattice relaxation up to 1000 nm. The average Al composition in the light emitting active region is similar to the n-type AlGaN to minimize the strain for similar reasons. In practice, the average Al composition of the active region is within ±0.1 from the n-type AlGaN layer. The average Al composition x of a multiple-quantum-well active region structure can be calculated by the following equation Eq. 1, in which x_{QW} and x_{QB} is the Al composition of the quantum well and quantum barrier, respectively, and d_{QW} and d_{QB} is the thickness of the respective layers:

$$\overline{x} = {\sum }_{i} {x}_{i} {d}_{i} = \frac{{x}_{QW} {d}_{QW} + {x}_{QB} {d}_{QB}}{{d}_{QW} + {d}_{QB}} \qquad Eq . 1$$

The Al composition of the quantum barrier should be much higher than the quantum well for their average composition to be similar to that of the n-type AlGaN layer. In practice, the difference in the Al composition between quantum well and quantum barrier should be at least 0.3.

Another advantage of using the present design for the active region is to increase the radiative recombination efficiency of such a device. Since the nitride material is polar, the radiative efficiency is often hindered by the QCSE from the high internal polarization fields present in the active region. The typical built-in electrical field in the quantum well of an AlGaN UV LED can be as high as a few mV/cm, which can be even higher when the difference in the Al composition between the quantum well and the quantum barrier is large. However, since the polarization field in the quantum well is proportional to the thickness of quantum barrier in a multiple-quantum-well (MQW) structure, the radiative efficiency of the device can be increased if the polarization field in the quantum well is reduced with a thinner barrier, which is shown later in the advantage and improvement section with more details. It was found that the quantum barrier thickness should be at most 10 nm, and preferably below 6 nm, to maximize the radiative recombination efficiency.

The device further comprises p-type AlGaN layers epitaxially grown above the active region with thicknesses ranging from 20 nm to 500 nm. The p-type AlGaN layers may contain Mg-doped short-period superlattice (SPSL) structure where the effective Mg dopant activation energy is reduced by the polarization field. The p-type layers may also contain a compositionally graded structure where the Al composition of the layer varies from x₁ to x₂ where x₁ is greater than x₂ on an Al-polar AlN substrate. In the case of the compositionally graded structure, the p-type cladding may be doped or unintentionally doped. An oxide layer may be deposited on or above the p-type AlGaN layers. In the case of an LED structure, such an oxide layer may be doped Ga₂O₃, ITO or other oxides with high conductivity to form a tunnel junction contact. In the case of a LD structure, such oxides may be Ga₂O₃, ITO, SiO₂ or other oxide materials transparent to the laser wavelength with lower refractive index than the p-type nitride layers to act as the p-cladding layer.

Overall, the present design provides a superior structure for UV LED or UV LD active regions with emission wavelengths below 360 nm on AlN substrates or AlN templates, by reducing defect generation and thus improving radiative recombination efficiency. The present invention also discloses UV LED and UV LD devices using the above-described structures.

### DESCRIPTION OF THE DRAWINGS

Referring now to the drawings in which like reference numbers represent corresponding parts throughout:

FIG. 1 is a cross-sectional schematic of a UV LED structure using the present invention in the active region.

FIG. 2 is a cross-sectional schematic of a UV LED structure using the present invention in the active region and using a transparent conducting oxide as the p-contact layer.

FIG. 3 is a cross-sectional schematic of a UV LD structure using the present invention in the active region.

FIG. 4 is a cross-sectional schematic of a UV LD structure using the present invention in the active region and using a transparent conducting oxide as the p-cladding layer.

FIG. 5 is a graph of Power @ 20 mA (mW) vs. QB thickness (nm) showing the 320 nm UV LED on-chip power at a current density of 20 mA with different quantum barrier thicknesses, showing the improved LED performance with thinner quantum barriers.

FIG. 6 is a graph of Power @ 20 mA (mW) vs. Barrier Composition (A1%) showing the 320 nm UV LED on-chip power at a current density of 20 mA with different quantum barrier Al compositions, showing the improved LED performance with higher Al composition in the quantum barrier.

FIG. 7 is a graph of Power @ 20 mA (mW) vs. Wavelength (nm) showing the UVB/UVA LED on-chip power at a current density of 20 mA versus wavelength using the present invention versus LEDs using the conventional design for the active region, illustrating superior performance in output power.

FIG. 8 is a flowchart illustrating a process for fabricating III-nitride device structures according to the present invention.

### DETAILED DESCRIPTION OF THE INVENTION

In the following description of the preferred embodiment, reference is made to the accompanying drawings which form a part hereof, and in which is shown by way of illustration a specific embodiment in which the invention may be practiced. It is to be understood that other embodiments may be utilized, and structural changes may be made without departing from the scope of the present invention.

### Technical Description

### First Embodiment

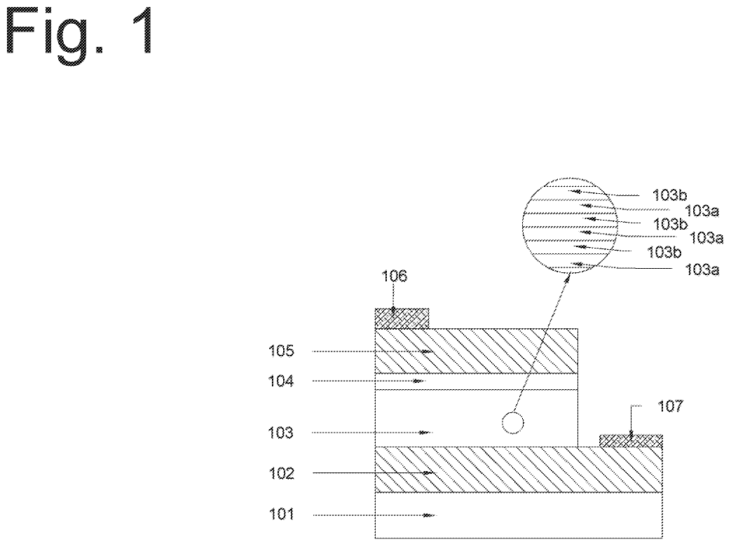

FIG. 1 is a cross-sectional schematic of a UV LED epitaxial structure, according to a first embodiment. This UV LED is comprised of an AlN layer 101, an n-type AlGaN layer 102, a light emitting active region layer 103 with quantum well layers 103a and quantum barrier layers 103b, an electron blocking layer 104, a p-type AlGaN layer 105, a p-contact layer 106, and an n-contact layer 107.

The AlN layer 101 can have thickness between 200 and 3000 nm, and can be deposited epitaxially on a SiC substrate, sapphire substrate, or bulk AlN substrate.

The n-type AlGaN layer 102 can have Si, Ge, O, C, or Fe as the n-type dopants and the dopant concentration is in the range of 10¹⁷ and 10²⁰ cm⁻³, preferably higher than 10¹⁸ cm⁻³. The n-type AlGaN layer 102 can have thickness between 100 nm to 2000 nm, preferably below 800 nm. The Al composition of n-type AlGaN layer 102 should be at least higher than the Al composition of the quantum well layers 103a.

The light emitting active region 103 contains at least one period of quantum well layers 103a and quantum barrier layers 103b. The Al composition of the quantum barrier layers 103b is at least 0.3 higher than the Al composition of the quantum well layers 103a. The average Al composition of the quantum well layers 103a and the quantum barrier layers 103b, as defined by Eq. 1 above, should be within +0.1 different from the average Al composition of n-type AlGaN layer 102. The thickness of the quantum barrier layers 103b should be less than 10 nm, and preferably less than 6 nm, when the UV LED emission wavelength is between 300 nm and 360 nm.

The electron blocking layer 104 can be unintentionally doped (UID) or doped by p-type dopants like Mg and has Al composition higher than or equal to the Al composition of quantum barrier layers 103b. The electron blocking layer 104 has thickness preferably ranging from 0 to 20 nm.

The p-type AlGaN layer 105 is formed on or above the electron blocking layer 104 and has thickness ranging from 10 nm to 300 nm, preferably below 50 nm. The p-type AlGaN layer 105 comprises either short period superlattice (SPSL) structures or three-dimensional (3D) polarization enhanced doping structures, or a combination of both. The SPSL structure comprises alternating AlₘGa₁₋ₘN/AlₙGa₁₋ₙN layers wherein m≠n, and preferably the difference in Al composition m and n is greater than or equal to 0.4. The p-type AlGaN layer 105 is doped by p-type dopants, preferably by Mg and has a dopant concentration preferably in the range of 10¹⁷ and 10²¹ cm⁻³. The 3D polarization enhanced doping structure comprises an AlₖGa₁₋ₖN layer, with 0≤k≤1, with a thickness preferably between 20 nm and 300 nm. The AlₖGa₁₋ₖN composition k is continuously varied along the growth direction. The composition profile depends on the polarity of the substrate. In the case of a c-plane nitride substrate, the AlₖGa₁₋ₖN composition k is continuously decreasing along the growth direction. The 3D polarization enhanced doping structure may also be unintentionally doped or doped with p-type dopants with an average concentration preferably between 10¹⁷ to 10²¹ cm⁻³. The p-type AlGaN layer 105 can also contain a p-GaN layer with thickness preferably ranging from 0 to 100 nm above the SPSL structure or the 3D polarization enhanced doping structure.

The p-contact layer 106 can be p-contact metal including but not limited to Ni, Pd, Pt, Al, Au, Rh, etc.

The n-contact layer 107 can be n-contact metal including but not limited to V, Ti, Ni, Al, Au, Pt, Rh, etc.

### Second Embodiment

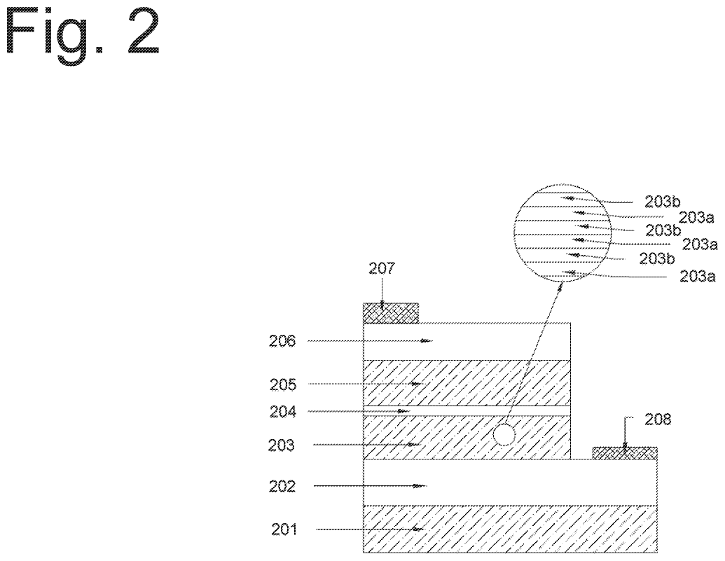

FIG. 2 is a cross-sectional schematic of a UV LED epitaxial structure, according to a first embodiment. This UV LED is comprised of an AlN layer 201, an n-type AlGaN layer 202, a light emitting active region layer 203 with quantum well layers 203a and quantum barrier layer 203b, an electron blocking layer 204, a p-type AlGaN layer 205, a transparent conducting oxide (TCO) layer 206, a p-contact layer 207, and an n-contact layer 208.

This UV LED has the same structure as the first embodiment, including the AlN layer 201, the n-type AlGaN layer 202, the active region layer 203, the electron blocking layer 204, and the p-type AlGaN layer 205, except that it also includes an additional TCO layer 206 underneath the p-contact layer 207. The transparent conducting oxide layer 206 can be at least 70% transparent, preferably fully transparent, to the emission wavelength from the active region. The transparent conducting oxide layer 206 can comprise an oxide composition having a formula GaₙAlₛInₜBᵤMgᵥFe_{w}SiₓSn_{y}O_{z} where all normalized constituent compositions n, s, t, u, v, W, x, y are between 0 and 1 and n+s+t+u+v+w+x+y=1. The transparent conducting oxide layer 206 may comprise an alpha, beta, gamma, delta, or epsilon phase of Ga₂O₃ with preferably (−201), (001), or (010) crystal orientation, or any other orientation. The transparent conducting oxide layer 206 may have a thickness between 100 nm and 500 nm, and may form a tunnel junction contact to the p-type AlGaN layer 205.

The p-contact layer 207 can be p-contact metal including but not limited to Ni, Pd, Pt, Al, Au, Rh, etc.

The n-contact layer 208 can be n-contact metal including but not limited to V, Ti, Ni, Al, Au, Pt, Rh, etc.

### Third Embodiment

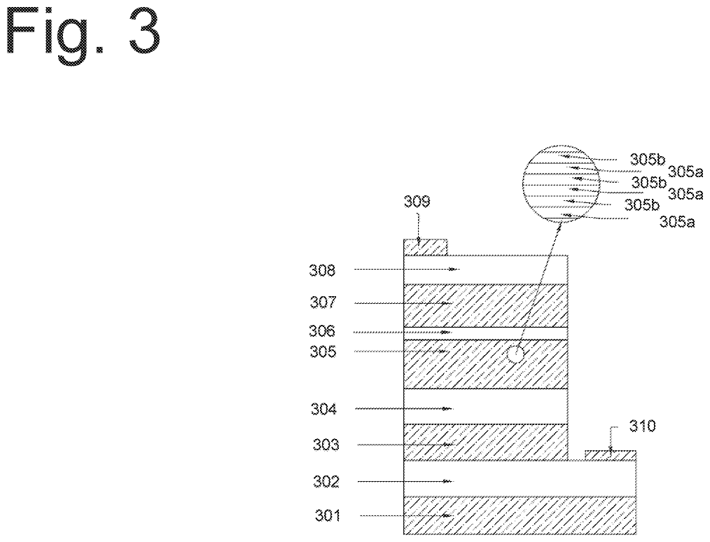

FIG. 3 is a cross-sectional schematic of a UV LD epitaxial structure, according to a third embodiment. This UV LD is comprised of an AlN substrate layer 301, a first n-type cladding layer 302, a second n-type cladding layer 303, a separate confinement heterogeneous structure (SCH) with an n-SCH layer 304 and a p-SCH layer 307, a light emitting active region layer 305 with quantum well layers 305a and quantum barrier layers 305b, an electron blocking layer 306, a p-type cladding layer 308, a p-contact layer 309, and an n-contact layer 310.

The AlN layer 301 can have thickness between 200 and 3000 nm, and can be deposited epitaxially on a SiC substrate, sapphire substrate or bulk AlN substrate.

The n-type AlGaN cladding layer 302 and n-type AlGaN cladding layer 303 can have Si, Ge, O, C, or Fe as the n-type dopants with the dopant concentration in a range of 10¹⁷ and 10²⁰ cm⁻³, preferably higher than 10¹⁸ cm⁻³. The Al composition of both the first n-type AlGaN cladding layer 302 and the second n-type AlGaN cladding layer 303 preferably should be at least higher than the Al composition of the quantum well layers 305a. The first n-type cladding layer 302 can be composed of a nano-porous n-AlGaN layer with a thickness between 0 and 800 nm, wherein the refractive index of the nano-porous n-AlGaN layer is preferably smaller than the n-SCH layer 304 and the second n-type nitride cladding layer 303 to efficiently confine the photons. The second n-type AlGaN cladding layer 303 can have a thickness between 100 nm to 2000 nm, and preferably below 600 nm.

The thickness of the n-SCH layer 304 and p-SCH layer 307 can be in a range of 20 nm to 200 nm. The n-SCH layer 304 can be UID or doped by n-type dopants at an average concentration below 10¹⁹ cm⁻³, and preferably one order of magnitude lower than the doping concentration in the n-type cladding layers 302 and 303.

The light emitting active region 305 contains at least one period of AlₓGa₁₋ₓN quantum well layers 305a, with 0≤x≤1, and Al_{y}Ga_{1-y}N quantum barrier layers 305b, with 0≤y≤1. The Al composition y of the Al_{y}Ga_{1-y}N quantum barrier layers 305b is preferably at least 0.3 higher than an Al composition x of the AlₓGa₁₋ₓN quantum well layers 305a, such that y>x+0.3. The thickness of the quantum barrier layers 305b should be less than 10 nm, and preferably less than 6 nm, when the UV LD emission wavelength is between 300 nm and 360 nm.

The bandgap energy of the n-SCH layer 304 and p-SCH layer 307 should be higher than the photon energy of the emitted light of the UV LD to confine the carriers of electrons and holes within the active region 305.

The electron blocking layer 306 can be UID or Mg-doped, preferably has a thickness ranging from 0 to 20 nm, and preferably has a higher Al composition than the p-SCH layer 307.

The p-type AlGaN cladding layer 308 is formed on or above the p-SCH layer 307, and has a thickness ranging from 10 nm to 400 nm. The p-type AlGaN cladding layer 308 comprises either SPSL structures or 3D polarization enhanced doping structures, or a combination of both. The doping, composition profile and the thickness of the p-SPSL and 3D polarization enhancement is the same as the p-type AlGaN layer 105 in the first embodiment.

The p-contact layer 309 can be p-contact metal including but not limited to Ni, Pd, Pt, Al, Au, etc.

The n-contact layer 310 can be n-contact metal including but not limited to V, Ti, Ni, Al, Au, Pt, etc.

### Fourth Embodiment

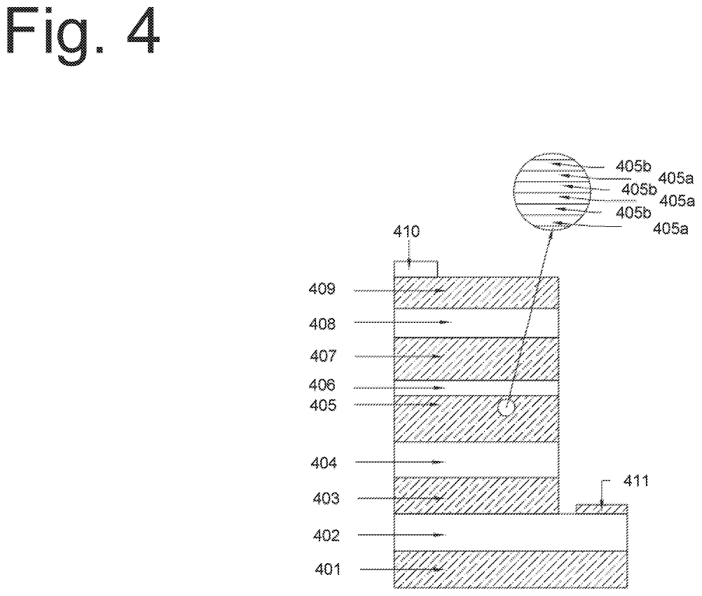

FIG. 4 is a cross-sectional schematic of a UV LD epitaxial structure, according to a fourth embodiment. This UV LD comprises an AlN substrate layer 401, a first n-type cladding layer 402, a second n-type cladding layer 403, a SCH structure with an n-SCH layer 404 and a p-SCH layer 407, a light emitting active region layer 405 with quantum well layers 405a and quantum barrier layers 405b, an electron blocking layer 406, a p-type cladding layer 408, a transparent oxide layer 409, a p-contact layer 410, and an n-contact layer 411.

This LD has the same structure for layers 401-408 as the third embodiment, except that it also includes an additional transparent oxide layer 409 above the p-type cladding layer 408. The transparent oxide layer 409 may be at least 70% transparent to the emission wavelength, and preferably fully transparent, and has a smaller refractive index than the p-type nitride cladding layer 408, to act as the second p-type cladding layer. The transparent conducting oxide layer 409 can be comprised of ITO or an oxide composition having a formula GaₙAlₛInₜBᵤMgᵥFe_{w}SiₓSn_{y}O_{z} where all normalized constituent compositions n, s, t, u, v, w, x, y are between 0 and 1 and n+s+t+u+v+w+x+y=1, and acts as a tunnel junction contact to the p-type cladding layer 408.

Electrical contact metals, such as V, Ti, Ni, Al, Au, Pt, etc., may be deposited on the oxide layer 409.

### Advantages and Improvements

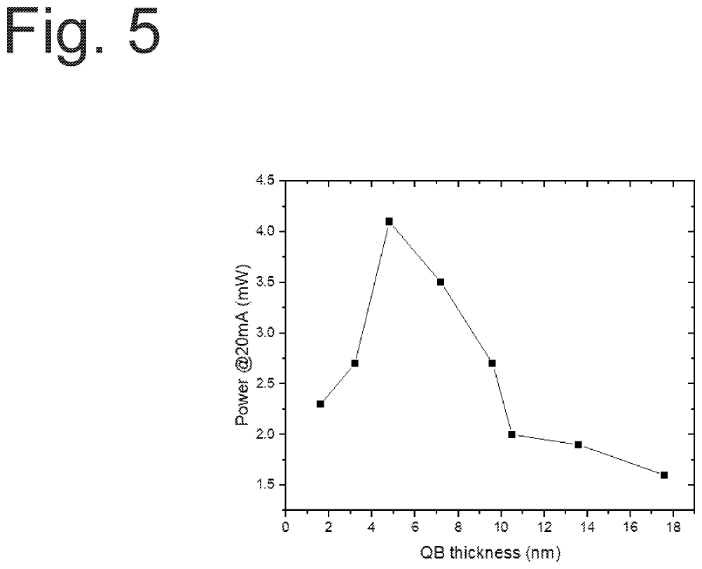

FIG. 5 shows the on-wafer power measurement of 320 nm band UV LEDs at a current density of 20 A/cm² with different quantum barrier thicknesses. The on-wafer power is below 2 mW @ 20 A/cm² when the quantum barrier thickness is greater than 10 nm but improves drastically once the quantum barrier thickness is below 10 nm and reaching above 4 mW when the thickness is below 6 nm. However, when the quantum barrier is too thin (thickness <3 nm, similar to the quantum well thickness), output power decreases. This indicates that the optimized thickness for a UVA LED on an AlN substrate is below 10 nm, and more preferably below 6 nm.

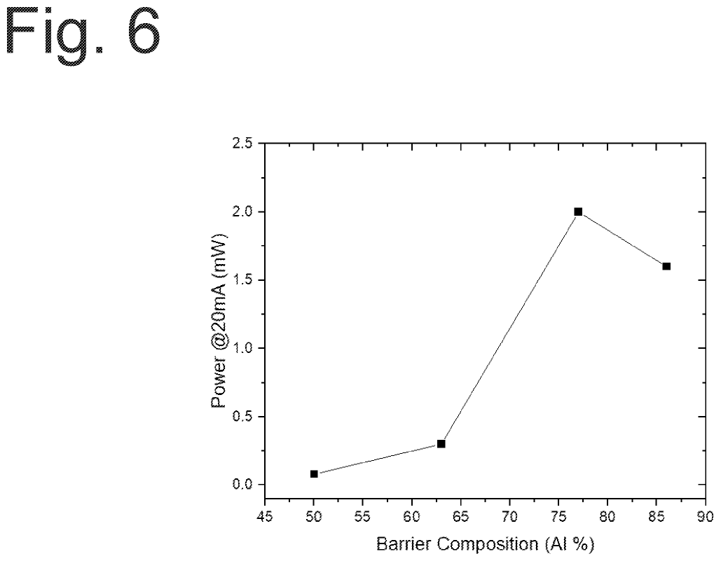

FIG. 6 shows the on-wafer power measurement of 320 nm band UV LEDs at a current density of 20 A/cm² with different quantum barrier Al compositions. It was found that the on-wafer power increased drastically with the increasing Al composition in the quantum barrier and becomes relatively constant when the Al composition in the quantum barrier is above 75%.

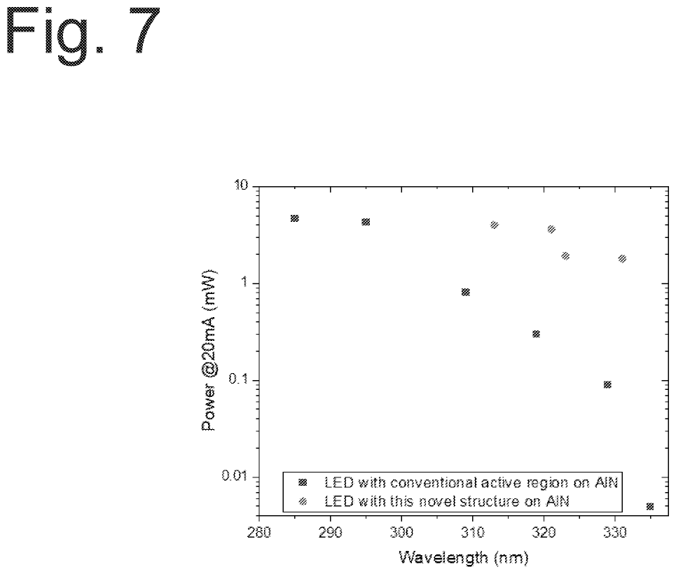

Both FIG. 5 and FIG. 6 illustrate that the novel active region design in the present invention yields superior device performance for UVA light emitters on the AlN substrate. Conventionally, UV LEDs have thick quantum barriers (>10 nm) and an Al composition in the quantum barrier that is only slightly higher than the Al composition in the quantum well (Al_{QB}-Al_{QW}~0.2) to minimize the potential barrier height for current injection to reduce operating voltage. However, the conventional design only works for UVB-UVC wavelengths (<300 nm) but fails in UVA wavelengths where the lattice mismatch between the active region and the substrate is significantly larger as compared to the UVB-UVC device designs. UVA emitters with thin quantum barriers with high Al content, as disclosed by the present invention, improves the on-wafer power performance significantly, as shown in FIG. 7, which can be attributed to the low defect density for growing highly strained active region, and the decreased QCSE with thinner quantum barriers.

### Process Steps

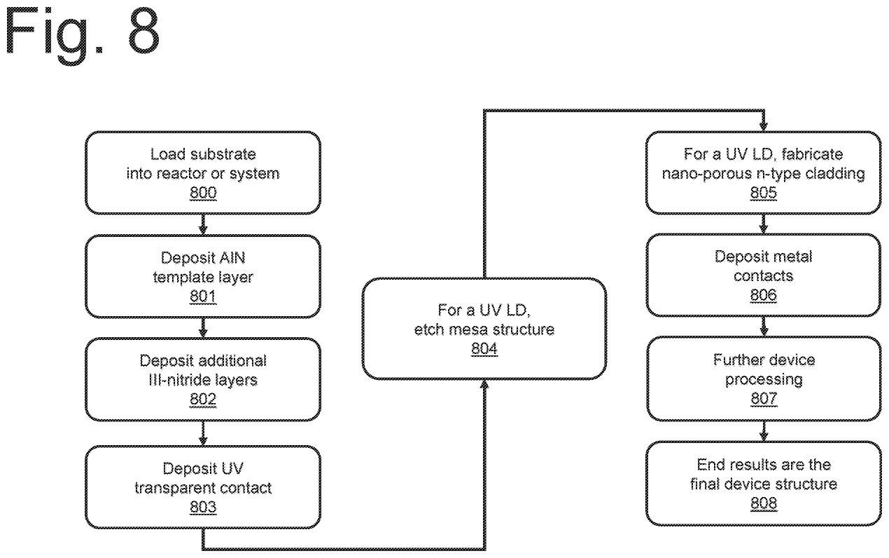

FIG. 8 is a flowchart that illustrates the steps for a process of fabricating a III-nitride based device, according to the present invention. Specifically, the flowchart illustrates the steps for a process of fabricating a III-nitride based optoelectronic device.

Block 800 represents the step of loading a substrate into a chamber of an MOCVD reactor or MBE system, wherein the substrate is a Sapphire, bulk AlN, or Silicon Carbide (SiC) substrate.

Block 801 represents the step of depositing an AlN template layer on or above the substrate.

Block 802 represents the step of depositing additional III-nitride layers for a UV LED or LD on or above the AlN layer. For both the UV LED and LD, this step includes forming at least one n-type region; forming at least one active region or light emitting region that contains at least one quantum well (QW) and quantum barrier (QB) structure; and forming at least one p-type region on or above the active region.

In one embodiment, the n-type region comprises an n-type AlₐGa₁₋ₐN layer, where 0≤a≤1, formed on or above the AlN layer and has in-plane lattice constant or strain at most 30% relaxed to that of the AlN layer. Moreover, the n-type AlₐGa₁₋ₐN layer is at least 300 nm thick and contains Si, Ge, O, C, or Fe as n-type dopants.

Preferably, the Al content of the quantum barrier is higher than a quantum barrier used in a conventional design of a UV LED or LD, and the thickness of the quantum barrier is thinner than a quantum barrier in a conventional design of a UV LED or LD. For example, the quantum barrier has a thickness that is less than 10 nm, and more preferably the quantum barrier has a thickness that is less than 6 nm, for light emission at a wavelength between 300-360 nm.

In one embodiment, the quantum well is an AlₓGa₁₋ₓN quantum well, where 0≤x≤1, and the quantum barrier is an Al_{y}Ga_{1-y}N quantum barrier, where Ogy≤1, with an Al composition y that is at least 0.3 higher than an Al composition x in the AlₓGa₁₋ₓN quantum well, such that y>x+0.3.

In one embodiment, the active region is formed on or above the n-type AlₐGa₁₋ₐN layer and a difference between an average Al composition z of the light emitting active region and an Al composition a of the n-type AlₐGa₁₋ₐN layer is less than 10%, and the average Al composition z can be calculated from a thickness tow of the quantum well and a thickness top of the quantum barrier, and the Al compositions x and y of the quantum well and quantum barrier, respectively, such that:

$$a - 0.1 \leq z = \frac{{t}_{QB} \times y + {t}_{QW} \times x}{{t}_{QB} + {t}_{QW}} \leq a + 0.1$$

Moreover, for the UV LD, this step may include forming a first cladding region on or above the n-type region; forming a first waveguide region on or above the first cladding region; forming the active region on or above the first waveguide region; forming a second waveguide region on or above the active region; forming a second cladding region on or above the second waveguide region; and forming the p-type region formed on or above the second cladding region.

In one embodiment, the first cladding region is comprised of a nano-porous layer; and/or the second cladding region is comprised of a TCO layer, where the TCO layer is comprised of an alloy composition having a formula GaₙAlₛInₜBᵤMgᵥFe_{w}SiₓSn_{y}O_{z} where all normalized constituent compositions n, s, t, u, v, w, x, y are between 0 and 1 and n+s+t+u+v+w+x+y=1.

In addition, the TCO layer may be comprised of an alpha, beta, gamma, delta, and epsilon phase of Ga₂O₃, and a (−201), (001), or (010) crystal orientation of Ga₂O₃. The TCO layer preferably is at least 70% or more transparent to the emitted UV light.

Block 803 represents the step of depositing at least one UV transparent contact on or above the p-type region.

This step may include forming the TCO layer 206 in the UV LED in the second embodiment or the oxide layer 409 in the UV LD in the fourth embodiment, using common oxide deposition techniques on the III-nitride layers, such as electron beam evaporation (e-beam), thermal evaporation, sputter, ion beam deposition (IBD), plasma enhanced chemical vapor deposition (PECVD), atomic layer deposition (ALD), MBE, MOCVD, etc.

For the UV LD, Block 804 represents the step of etching the III-nitride layers into a mesa structure to expose the n-type AlGaN layers for n-contacts and forming ridge facets using common semiconductor technology including reactive ion etching (RIE), inductive coupled plasma RIE etching (ICP), plasma etching, ion milling, etc. The UV LED skips this step.

For the UV LD, Block 805 represents the step of fabricating the nano-porous n-type cladding layer 302, 402 in the third and fourth embodiment using electrochemical etching techniques. The nano-porous structure can be fabricated with electrochemical wet etching. Si-doped nitride layers can be etched in an acidic solution, preferably in the oxalic acid solution after a voltage drop is applied. The porosity (volume/size of pores) can vary with the applied voltage bias and etching duration. The UV LED skips this step.

Block 806 represents the step of depositing metal contacts using common metal deposition techniques such as electron beam evaporation or thermal evaporation.

Block 807 represents the step of further device processing, as necessary.

Block 808 represents the end results of the method, namely, the final device structure. In one embodiment, the active region of the device emits UV light with an emission wavelength between 300 nm and 370 nm, and the n-type region, the p-type region and the UV transparent contact of the device are fully or partially transparent to the UV light.

### Nomenclature

The terms “Group-III nitrides” or “III-nitrides” or “nitrides” as used herein refer to any alloy composition of the (Ga, Al, In, B) N semiconductors having the formula GaₙAlₓIn_{y}B_{z}N where 0≤n≤1, 0≤x≤1, 0≤y≤1, 0≤z≤<1, and n+x+y+z=1.

These terms as used herein are intended to be broadly construed to include respective nitrides of the single species, Ga, Al, In and B, as well as binary, ternary and quaternary compositions of such Group III metal species. Accordingly, these terms include, but are not limited to, the compounds of AlN, GaN, InN, AlGaN, AlInN, InGaN, and AlGalnN. When two or more of the (Ga, Al, In, B) N component species are present, all possible compositions, including stoichiometric proportions as well as off-stoichiometric proportions (with respect to the relative mole fractions present of each of the (Ga, Al, In, B) N component species that are present in the composition), can be employed within the broad scope of this invention. Further, compositions and materials within the scope of the invention may further include quantities of dopants and/or other impurity materials and/or other inclusional materials.

### REFERENCES

The following publications are incorporated by reference herein:
[1] T. Matsumoto, M. Ajmal Khan, N. Maeda, S. Fujikawa, N. Kamata, and H. Hirayama, “Milliwatt power UV-A LEDs developed by using n-AlGaN superlattice buffer layers grown on AlN templates,” J Phys D Appl Phys, vol. 52, no. 11, January 2019, doi: 10.1088/1361-6463/aaf60a.
[2] K. Iida et al., “350.9 nm UV laser diode grown on low-dislocation-density AlGaN,” Japanese Journal of Applied Physics, Part 2: Letters, vol. 43, no. 4 A, April 2004, doi: 10.1143/jjap.43.1499.

### CONCLUSION

This concludes the description of the preferred embodiment of the present invention. The foregoing description of one or more embodiments of the invention has been presented for the purposes of illustration and description. It is not intended to be exhaustive or to limit the invention to the precise form disclosed. Many modifications and variations are possible in light of the above teaching. It is intended that the scope of the invention be limited not by this detailed description, but rather by the claims appended hereto.

What is claimed is:

1. An optoelectronic device, comprising:
a substrate;
an n-type region formed on or above the substrate;
an active region formed on or above the n-type region; and
a p-type region formed on or above the active region;
wherein the active region is a light emitting region that emits ultraviolet (UV) light and the light emitting region contains at least one quantum well (QW) and quantum barrier (QB) structure in which the quantum barrier thickness is less than 10 nm.

2. The device of claim 1, wherein the quantum barrier thickness is less than 6 nm for light emission at a wavelength between 300-360 nm.

3. The device of claim 2, wherein the quantum well is an AlₓGa₁₋ₓN quantum well, where 0≤x≤1, the quantum barrier is an Al_{y}Ga_{1-y}N quantum barrier, where 0≤y≤1, and an Al composition y of the Al_{y}Ga_{1-y}N quantum barrier is at least 0.3 higher than an Al composition x in the AlₓGa₁₋ₓN quantum well, such that y>x+0.3.

4. The device of claim 3, wherein the n-type region comprises an n-type AlₐGa₁₋ₐN layer, where 0≤a≤1, the active region is formed on or above the n-type AlₐGa₁₋ₐN layer, a difference between an average Al composition z of the active region and an Al composition a of the n-type AlₐGa₁₋ₐN layer is less than 10%, and the average Al composition z is calculated from a thickness tow of the AlₓGa₁₋ₓN quantum well and a thickness top of the Al_{y}Ga_{1-y}N quantum barrier, and the Al compositions x and y of the AlₓGa₁₋ₓN quantum well and Al_{y}Ga_{1-y}N quantum barrier, respectively, such that:
$$a - 0.1 \leq z = \frac{{t}_{QB} \times y + {t}_{QW} \times x}{{t}_{QB} + {t}_{QW}} \leq a + 0.1$$

5. The device of claim 4, wherein the substrate further comprises an AlN template on a sapphire, SiC or bulk AlN substrate.

6. The device of claim 5, wherein the n-type AlₐGa₁₋ₐN layer is formed on or above the AlN layer and has in-plane lattice constant or strain at most 30% relaxed to that of the AlN layer.

7. The device of claim 4, wherein the n-type AlₐGa₁₋ₐN layer is at least 300 nm thick and contains Si, Ge, O, C, or Fe as n-type dopants.

8. The device of claim 1, wherein the p-type region contains Mg, Zn, O, C, or Fe as p-type dopants.

9. An optoelectronic device, comprising:
a substrate;
an n-type region formed on or above the substrate;
a first cladding region formed on or above the n-type region;
a first waveguide region formed on or above the first cladding region;
an active region formed on or above the first waveguide region;
a second waveguide region formed on or above the active region;
a second cladding region formed on or above the second waveguide region; and
a p-type region formed on or above the second cladding region;
wherein the active region is a light emitting region that emits ultraviolet (UV) light and the light emitting region contains at least one quantum well (QW) and quantum barrier (QB) structure in which the quantum barrier (QB) thickness is less than 10 nm.

10. The device of claim 9, wherein the quantum barrier thickness is less than 6 nm.

11. The device of claim 9, wherein the quantum barrier has an Al composition that is at least 0.3 higher than an Al composition in the quantum well.

12. The device of claim 9, wherein the first cladding region is comprised of a nano-porous layer.

13. The device of claim 9, wherein the second cladding region is comprised of a transparent conducting oxide (TCO) layer.

14. The device of claim 13, wherein the transparent conducting oxide layer is comprised of an alloy composition having a formula GaₙAlₛInₜBᵤMgᵥFe_{w}SiₓSn_{y}O_{z} where all normalized constituent compositions n, s, t, u, v, w, x, y are between 0 and 1 and n+s+t+u+v+w+x+y=1.

15. The device of claim 14, wherein the transparent conducting oxide layer is comprised of an alpha, beta, gamma, delta, or epsilon phase of Ga₂O₃.

16. The device of claim 14, wherein the transparent conducting oxide layer is comprised of a (−201), (001), or (010) crystal orientation of Ga₂O₃.

17. The device of claim 13, wherein the transparent conducting oxide layer is at least 70% or more transparent to the emitted UV light.

18. A method of fabricating an optoelectronic device, comprising:
forming at least one n-type region on a substrate;
forming at least one active region on or above the n-type region, wherein the active region contains at least one quantum well (QW) and quantum barrier (QB) structure in which the quantum barrier (QB) thickness is less than 6 nm;
forming at least one p-type region on or above the active region; and
forming at least one ultraviolet transparent contact on or above the p-type region;
wherein the active region emits ultraviolet (UV) light, and the n-type region, the p-type region and the ultraviolet transparent contact are fully or partially transparent to the UV light.
